(19) United States
(12) Patent Application Publication
(10) Pub. No.: US 2011/0174528 A1
(43) Pub. Date: Jul. 21, 2011

(54) METHOD OF FORMING CIRCUIT INTERCONNECTION, CIRCUIT BOARD, AND CIRCUIT INTERCONNECTION FILM HAVING FILM THICKNESS LARGER THAN WIDTH THEREOF

(75) Inventor: Tomoyuki KAMAKURA, Matsumoto (JP)

(73) Assignee: SEIKO EPSON CORPORATION, Tokyo (JP)

(21) Appl. No.: 13/008,335

(22) Filed: Jan. 18, 2011

(30) Foreign Application Priority Data
Jan. 21, 2010 (JP) 2010-010722

(51) Int. Cl. H05K 1/11; H01B 5/00; H05K 3/12

(52) U.S. Cl. 174/262; 174/126.1; 427/98.5; 427/555

(57) ABSTRACT

A method of forming a circuit interconnection on a circuit board includes: forming a trench that corresponds to a shape of the circuit interconnection on an interconnection base material that forms the circuit interconnection; distributing a catalyst for forming a conductive layer on the trench; and forming a conductive circuit interconnection film that forms the circuit interconnection by distributing a plating solution in a range that includes the trench and depositing a conductive material from the plating solution through the catalyst for forming the conductive layer.

### BACKGROUND

1. Technical Field

The present invention relates to a method of forming a circuit interconnection on a circuit board, a circuit board formed using the method of forming a circuit interconnection, and a circuit interconnection film which is formed using the corresponding method of forming a circuit interconnection and has a film thickness that is greater than a width thereof.

2. Related Art

Up until now, semiconductor devices have been packaged and used on circuit boards. Recently, with the remarkable development of high-performance miniaturized semiconductor devices, miniaturized high-performance circuit boards for mounting the semiconductor device have also come into demand. In order to achieve miniaturized circuit boards, miniaturized high-density circuit interconnections that form the circuit boards are necessary. In order to make high-performance circuit boards, low resistance circuit interconnections (which have a large cross-sectional area and no defect) are necessary.

JP-A-2005-12181 discloses a method of forming a pattern, a device and a method of manufacturing the device, an electro-optic device, an electronic device, and a method of manufacturing an active matrix substrate. A method of forming a pattern is disclosed, which facilitates the insertion of a functional solution into a circuit interconnection forming area by distributing the functional solution that contains metal as a pattern forming method, forming a portion partially having a wide width on an area where a circuit interconnection is formed as a method of forming the circuit interconnection by solidifying the corresponding functional solution, and inserting the functional solution from the portion having the wide width.

JP-A-2009-117415 discloses a method of forming a circuit which can form a circuit pattern having a thick pattern thickness by forming the circuit pattern, forming an insulating resin layer that covers the corresponding circuit pattern, forming a trench that exposes the circuit pattern on the insulating resin layer, and arranging metal on the trench.

However, according to the method as disclosed in JP-A-2005-12181, if the functional solution containing metal flows into the circuit interconnection forming area, there is a possibility that the functional solution is not sufficiently filled into a portion having a narrow width of the circuit interconnection forming area due to the unevenness of the flow distribution, and thus the film thickness of the circuit interconnection film that forms the circuit interconnection is liable to become non-uniform.

According to the method as disclosed in JP-A-2009-117415, it is impossible to make the width of a circuit interconnection smaller than a predetermined width due to the fact that the width of the circuit interconnection is unable to be smaller than the width of the interconnection of the circuit pattern initially formed. For example, if an ink jet method according to a third aspect of the invention is used, a pattern having a width that is smaller than the landed diameter of the discharged and landed droplets is unable to be formed, and thus the miniaturization thereof is limited.

### SUMMARY

An advantage of some aspects of the invention is to solve at least a portion of the above-described problem, and it is possible to realize the invention with the following types or application examples.

### Application Example 1

According to this application example of the invention, there is provided a method of forming a circuit interconnection on a circuit board including a trench forming process of forming a trench that corresponds to a shape of the circuit interconnection on an interconnection base material that forms the circuit interconnection; a catalyst distribution process of distributing a catalyst for forming a conductive layer on the trench; and a film forming process of forming a conductive circuit interconnection film that forms the circuit interconnection by distributing a plating solution in a range that includes the trench and depositing a conductive material from the plating solution through the catalyst for forming the conductive layer.

According to the method of forming a circuit interconnection according to this application example, since a metal film is deposited from the plating solution by the catalyst for forming the conductive layer, the metal film can be selectively formed only on a portion where the catalyst is distributed. Since the catalyst for forming the conductive layer is formed on the trench as a metal catalyst that becomes the nucleation site of the plating, it has no effect on the film thickness of the circuit interconnection film. Also, for example, since the conductive material is deposited by plating such as electroless plating, the possibility is substantially removed of the circuit interconnection film that forms the circuit interconnection becoming non-uniform, and thus a uniform circuit interconnection can be formed.

It is possible to select a liquid body having low viscosity and sufficient fluidity as the catalyst for forming the conductive layer, and consequently the catalyst can be easily distributed even in a fine groove. Since the trench can be formed by carving a groove on the interconnection base material, a fine deep trench can be easily formed. By distributing the catalyst for forming the conductive layer in the fine deep trench and depositing the metal film from the plating solution through the corresponding catalyst for forming the conductive layer, the circuit interconnection film, which has substantially the same shape as that of the fine deep trench and has a narrow pattern width in a plane direction of the interconnection base material, can be easily formed. Since the width in the plane direction of the interconnection base material is fine, even a circuit interconnection film, of which the thickness in a direction that is substantially orthogonal to the plane direction of the interconnection base material is greater than the width in the plane direction of the interconnection base material, can be easily formed.

### Application Example 2

In the method of forming a circuit interconnection according to the above-described application example, it is preferable that the catalyst distributing process includes distributing a functional solution that includes the catalyst for forming the conductive layer, and a base material surface liquid repellent process of performing a liquid repellent process of the base material surface of the interconnection base material with respect to the functional solution that includes the catalyst for forming the conductive layer, wherein the base material surface liquid repellent process is performed prior to the trench forming process.

According to this method of forming a circuit interconnection, since the base material surface of the interconnection base material has a liquid repellent property against the functional solution that includes the catalyst for forming the conductive layer, the distribution of the catalyst for forming the conductive layer on the base material surface can be suppressed. By suppressing the distribution of the catalyst for forming the conductive layer on the base material surface on which the trench is formed, the conductive layer is formed on the base material surface, and the corresponding conductive layer can suppress a short-circuit between the conductive layers formed inside the trench.

### Application Example 3

In the method of forming a circuit interconnection according to the above-described application example, it is preferable that the trench is formed by a laser process in the trench forming process.

According to this method of forming a circuit interconnection, by narrowing the diameter of a laser light, a fine laser process becomes possible, and using a laser process as the method of forming the trench, a trench having a fine line width can be formed, and the trench can be formed precisely. Even a fine trench having a depth larger than the width can be easily formed.

### Application Example 4

The method of forming a circuit interconnection according to the above-described application example may further include a desmear processing process.

According to this method of forming a circuit interconnection, smear can be removed by the desmear processing process. By removing the smear inside the trench and on aside wall thereof, it is easy to deposit the functional solution that includes the catalyst for forming the conductive layer onto the circuit interconnection film, and thus it is possible to suppress the occurrence of a defect on the circuit interconnection film due to the fact that the functional solution that includes the catalyst for forming the conductive layer is not filled onto the circuit interconnection film.

### Application Example 5

In the method of forming a circuit interconnection according to the above-described application example, it is preferable that the catalyst distribution process includes landing and distributing the functional solution that includes the catalyst for forming the conductive layer on a portion of the trench using an ink jet type discharge device.

According to this method of forming a circuit interconnection, the functional solution that includes the catalyst for forming the conductive layer is distributed on the trench using an ink jet type discharge device. The ink jet type discharge device can distribute an arbitrary amount of the liquid body on an arbitrary position precisely. Accordingly, the functional solution can be distributed on a proper position of the fine trench precisely. Also, an appropriate amount of the functional solution to be distributed can be distributed moderately.

### Application Example 6

In the method of forming a circuit interconnection according to the above-described application example, it is preferable that the catalyst distribution process includes distributing the functional solution that includes the catalyst for forming the conductive layer on a portion having a wide width of the trench, and distributing the distributed functional solution on the portion except for the portion having wide width by capillary force.

According to this method of forming a circuit interconnection, the functional solution can be distributed even in a fine portion by using capillary force. In the case of directly distributing the functional solution to a small trench, the functional solution can be distributed even on the fine trench, around which the functional solution is distributed due to the small size of the trench, without substantially flowing out.

### Application Example 7

In the method of forming a circuit interconnection according to the above-described application example, it is preferable that the film forming process includes forming the circuit interconnection film by electroless plating.

According to this method of forming a circuit interconnection, the circuit interconnection film can be selectively formed on the trench portion on which the catalyst for forming the conductive layer is distributed by electroless plating.

### Application Example 8

In the method of forming a circuit interconnection according to the above-described application example, it is preferable that the film forming process includes forming the circuit interconnection film by electroless plating and forming the circuit interconnection film by electro plating.

According to this method of forming a circuit interconnection, the circuit interconnection film can be selectively formed on the trench portion on which the catalyst for forming the conductive layer is distributed by electroless plating. By using both electroless plating and electro plating, the time required for forming the film can be shortened in comparison to a case where the circuit interconnection film is formed only by electroless plating.

### Application Example 9

According to this application example of the invention, there is provided a circuit board including a circuit interconnection that is formed using a method of forming a circuit interconnection which includes a trench forming process of forming a trench that corresponds to a shape of the circuit interconnection on an interconnection base material that forms the circuit interconnection; a catalyst distribution process of distributing a catalyst for forming a conductive layer on the trench; and a film forming process of forming a conductive circuit interconnection film that forms the circuit interconnection by distributing a plating solution in a range that includes the trench and depositing a conductive material from the plating solution through the catalyst for forming the conductive layer.

According to the circuit board of this application example which has the circuit interconnection formed by the method of forming the circuit interconnection, since a metal film is deposited from the plating solution by the catalyst for forming the conductive layer, the metal film can be selectively formed only on a portion where the catalyst is distributed. Since the catalyst for forming the conductive layer is formed on the trench as a metal catalyst that becomes the nucleation site of the plating, the film thickness deviation is quite a small level. Also, since the conductive material is deposited by plating such as electroless plating, the possibility is substantially removed of the circuit interconnection film that forms the circuit interconnection becoming non-uniform, and thus a uniform circuit interconnection can be formed.

It is possible to select a liquid body having low viscosity and sufficient fluidity as the catalyst for forming the conductive layer, and consequently the catalyst can be easily distributed even in a fine groove. Since the trench can be formed by carving a groove on the interconnection base material, a fine deep trench can be easily formed. By distributing the catalyst for forming the conductive layer in the fine deep trench and depositing the metal film from the plating solution through the corresponding catalyst for forming the conductive layer, the circuit interconnection film, which has substantially the same shape as that of the fine deep trench and has a fine width in a plane direction of the interconnection base material, can be easily formed.

Accordingly, since the fine circuit interconnection which is uniform and has the circuit interconnection film having a fine width in the plane direction of the circuit board can be formed, the circuit board that can suppress the enlargement thereof due to the fact that the circuit interconnection is unable to be fine can be realized.

### Application Example 10

In the circuit board according to the above-described application example, it is preferable that the catalyst distribution process includes distributing the functional solution that includes the catalyst for forming the conductive layer on a portion having a wide width of the trench, and distributing the distributed functional solution on the portion except for the portion having wide width by capillary force.

According to this circuit board, the functional solution can be distributed even in a fine portion by using capillary force when the circuit interconnection having the circuit board is formed. In the case of directly distributing the functional solution to a small trench, the functional solution can be distributed even on the fine trench, around which the functional solution is distributed due to the small size of the trench, without substantially flowing out.

### Application Example 11

According to this application example of the invention, there is provided a circuit interconnection film, which has a film thickness that is larger than a width of the interconnection film, and is formed using a method of forming a circuit interconnection film that includes a trench forming process of forming a trench that corresponds to a shape of the circuit interconnection film on an interconnection base material that forms the circuit interconnection film; a catalyst distribution process of distributing a catalyst for forming a conductive layer on the trench; and a film forming process of forming a conductive circuit interconnection film by distributing a plating solution in a range that includes the trench and depositing a conductive material from the plating solution through the catalyst for forming the conductive layer.

According to the circuit interconnection film which has a film thickness that is larger than a width of the interconnection film of this application example, and is formed using a method of forming a circuit interconnection film, since a metal film is deposited from the plating solution by the catalyst for forming the conductive layer, the metal film can be selectively formed only on a portion where the catalyst is distributed. Since the catalyst for forming the conductive layer is formed on the trench as a metal catalyst that becomes the nucleation site of plating, it has no effect on the film thickness of the circuit interconnection film. Also, since the conductive material is deposited by plating such as electroless plating, the possibility is substantially removed of the circuit interconnection film becoming non-uniform. Accordingly, a uniform circuit interconnection film can be formed.

It is possible to select a liquid body having low viscosity and sufficient fluidity as the catalyst for forming the conductive layer, and consequently the catalyst can be easily distributed even in a fine groove. Since the trench can be formed by carving a groove on the interconnection base material, a fine deep trench can be easily formed. By distributing the catalyst for forming the conductive layer in the fine deep trench and depositing the metal film from the plating solution through the corresponding catalyst for forming the conductive layer, the circuit interconnection film, which has substantially the same shape as that of the fine deep trench and has a fine width in a plane direction of the interconnection base material, can be easily formed.

Accordingly, since the uniform circuit interconnection film having a fine width in the plane direction of the interconnection base material can be easily formed, the circuit interconnection film having the film thickness that is larger than the width of the interconnection film can be easily formed.

### Application Example 12

In the circuit interconnection film having the film thickness that is larger than the width of the interconnection film according to the above-described application example, it is preferable that the catalyst distribution process includes distributing the functional solution that includes the catalyst for forming the conductive layer on a portion having a wide width of the trench, and distributing the distributed functional solution on the portion except for the portion having wide width by capillary force.

According to this circuit interconnection film having the film thickness that is larger than the width of the interconnection film, the functional solution can be distributed even in a fine portion by using capillary force when the circuit interconnection film is formed. In the case of directly distributing the functional solution to a narrow trench, the functional solution can be distributed even on the fine trench, around which the functional solution is distributed due to the narrow width of the trench, without substantially flowing out.

### BRIEF DESCRIPTION OF THE DRAWINGS

The invention will be described with reference to the accompanying drawings, wherein like numbers reference like elements.

FIG. 1A is a plan view illustrating an outline of a circuit board.

FIG. 1B is a cross-sectional view illustrating the cross-section of connection lines provided in a circuit board.

FIG. 2 is a flowchart illustrating a circuit interconnection forming process.

FIG. 3A is an explanatory view illustrating a cross-section of a base material body before a circuit interconnection is formed.

FIG. 3B is an explanatory view illustrating a cross-section of a trench.

FIG. 3C is an explanatory view illustrating an enlarged cross-section of a trench.

FIG. 3D is an explanatory view illustrating the shape of a desmear process.

FIG. 3E is an explanatory view illustrating an enlarged cross-section of a trench after a desmear process.

FIG. 4A is an explanatory view illustrating an distribution state of a catalyst functional solution.

FIG. 4B is an explanatory view illustrating a plane shape of a trench in the vicinity of a via forming place.

FIG. 4C is an explanatory view illustrating a state where an electroless plating solution is supplied.

FIG. 4D is an explanatory view illustrating a state where connection lines are partially formed by electroless plating.

FIG. 4E is an explanatory view illustrating a cross-section of a circuit board on which connection lines are formed.

### DESCRIPTION OF EXEMPLARY EMBODIMENTS

Hereinafter, a method of forming a circuit interconnection, a circuit board, and a circuit interconnection film having a film thickness that is larger than the width of the interconnection film will be described with reference to the accompanying drawing. In embodiments of the invention, a circuit board for packaging a semiconductor device and a process of forming a circuit interconnection on the circuit board will be described as an example. In the drawings which are referred to in the following description of the invention, for convenience in illustration, horizontal and vertical dimensions of members or portions may differ from the actual dimensions.

### Circuit Board

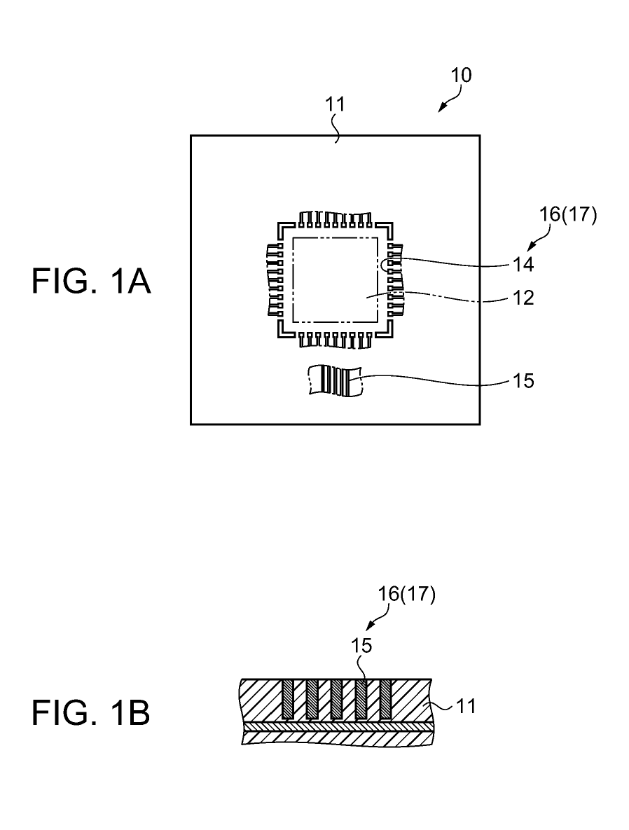

First, a circuit board 10 will be described with reference to FIGS. 1A and 1B. FIGS. 1A and 1B illustrate an outline of a circuit board. FIG. 1A is a plan view illustrating an outline of a circuit board, and FIG. 1B is a cross-sectional view illustrating the cross-section of connection lines provided in a circuit board.

The circuit board 10 is a package board on which a semiconductor device is packaged and then sealed on the board. As illustrated in FIG. 1A, a chip area 12 for installing a semiconductor chip thereon is installed substantially in the center of the circuit board 10, and a die pad 14 is formed around the chip area 12. The circuit board 10 is provided with a circuit interconnection 16 made of a good conductor such as copper. The circuit interconnection 16 is composed of terminals such as a die pad 14, connection lines 15 connecting between terminals of the die pad 14 and the like, and a circuit interconnection film 17 such as through-holes or lands of the through-holes, which are combined together.

As illustrated in FIG. 1B, the connection lines 15 correspond to a circuit interconnection film 17 having a cross-section which has a film thickness that is larger than the width of the interconnection film. The width-to-thickness aspect ratio is, for example, 5 to 10. With such a cross-sectional shape, the pitch of the connection lines 15 on the surface of a base material body 11 that is a base material of the circuit board 10 is sufficiently narrow, and the cross-sectional area of the connection lines 15 is enough for wiring conductivity.

### Process of Forming a Circuit Interconnection

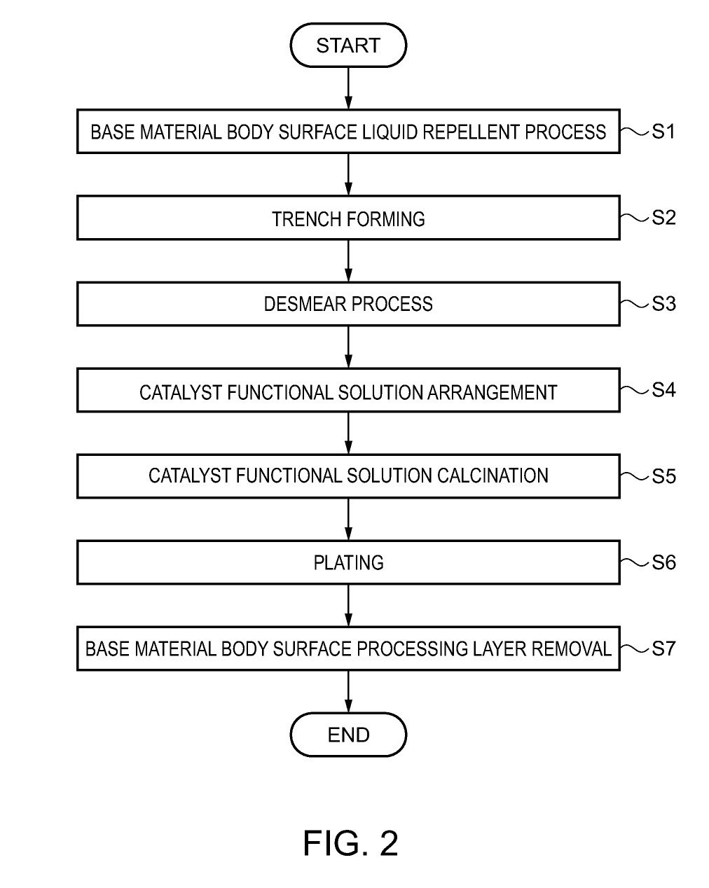

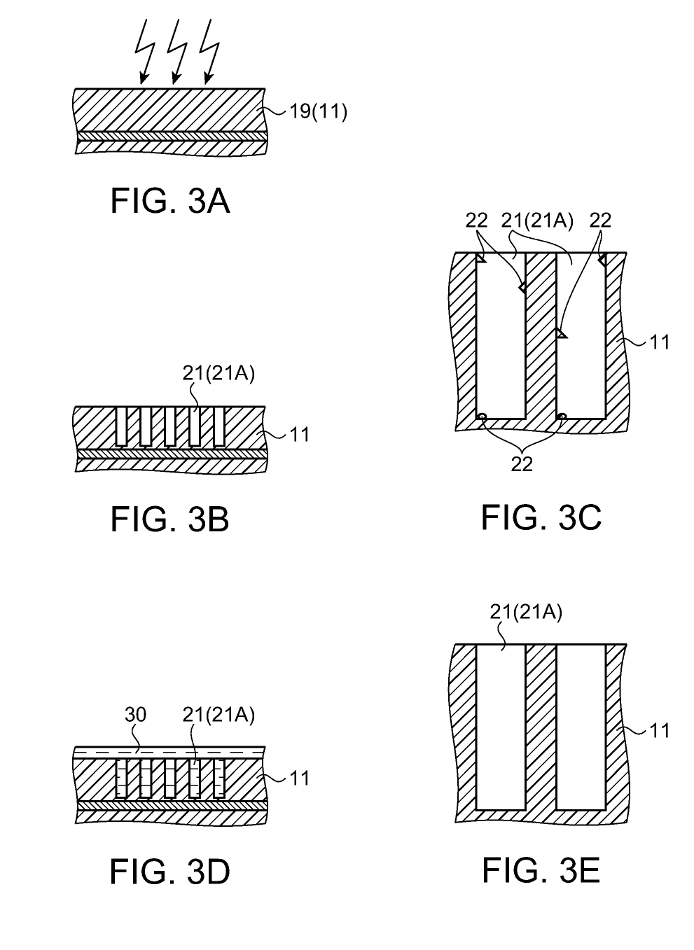

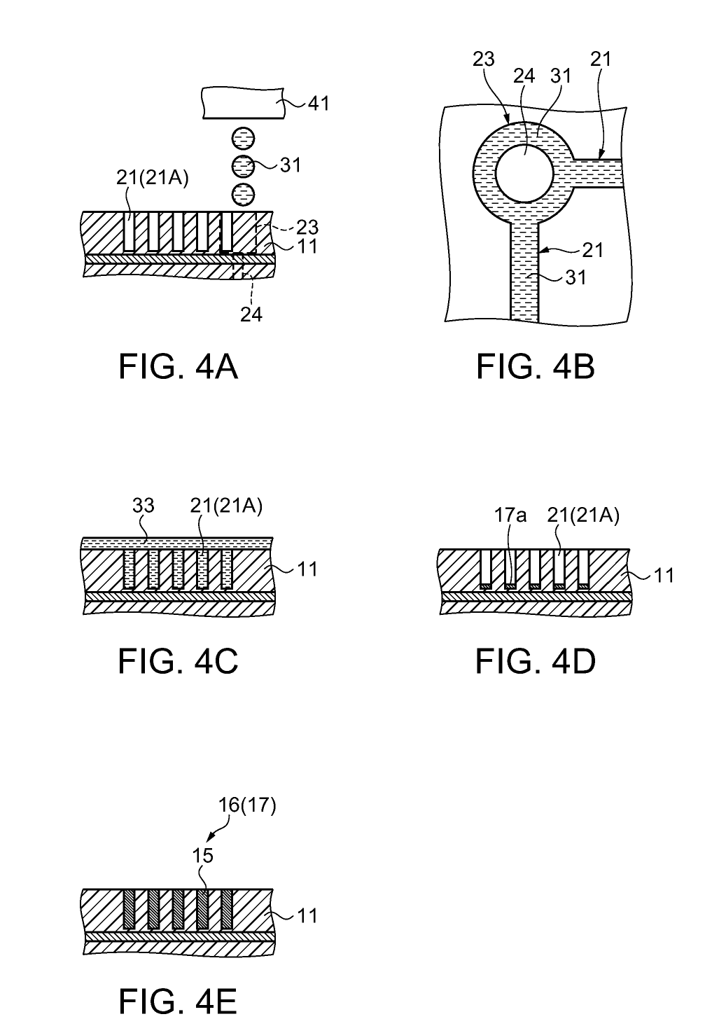

Next, a process of forming a circuit interconnection will be described with reference to FIGS. 2, 3A to 3E, and 4A to 4E. FIG. 2 is a flowchart illustrating a circuit interconnection forming process. FIGS. 3A to 3E and 4A to 4E are explanatory views illustrating the state of a circuit board in respective processes of the process of forming a circuit interconnection. FIG. 3A is an explanatory view illustrating a cross-section of a base material body before a circuit interconnection is formed, FIG. 3B is an explanatory view illustrating a cross-section of a trench, FIG. 3C is an explanatory view illustrating an enlarged cross-section of a trench, FIG. 3D is an explanatory view illustrating the shape of a desmear process, and FIG. 3E is an explanatory view illustrating an enlarged cross-section of a trench after a desmear process. FIG. 4A is an explanatory view illustrating an distribution state of a catalyst functional solution, FIG. 4B is an explanatory view illustrating a plane shape of a trench in the neighborhood of a via forming place, FIG. 4C is an explanatory view illustrating a state where an electroless plating solution is supplied, FIG. 4D is an explanatory view illustrating a state where connection lines are partially formed by electroless plating, and FIG. 4E is an explanatory view illustrating a cross-section of a circuit board on which connection lines are formed.

First, in step S1 of FIG. 2, a liquid repellent process for performing a liquid repellent operation of the surface of the base material body 11 with respect to a catalyst functional solution 31 (see FIGS. 4A and 4B). As illustrated in FIG. 3A, the base material body 11 is formed by laminating a prepreg 19. A liquid repellent process is performed with respect to the surface of the prepreg 19 that forms the circuit interconnection film 17 in the base material body 11. More preferably, the corresponding liquid repellent process is performed even with respect to an electroless plating solution 33 (see FIG. 4C). In this case, the base material body 11 is inscribed even with respect to a state before forming the circuit interconnection film 17 as illustrated in FIG. 3A, a state in the case where the circuit interconnection layer 17 has been formed as illustrated in FIG. 4E, and a state while the circuit interconnection film 17 is being formed. The base material body 11 in a state before the circuit interconnection film 17 is formed corresponds to the interconnection base material.

The liquid repellent process is performed using a CF4 plasma process using tetrafluorocarbon (tetrafluoromethane) as a process gas. By performing the CF4 plasma process, a liquid repellent film is formed on the surface of the base material body 11. The forming of the liquid repellent film may be performed by spreading a modification solution for modifying the material to have a liquid repellent property or by depositing the liquid repellent film through spreading of the liquid body that includes the material of the liquid repellent film. For example, the liquid repellent film may be formed by spreading or distributing in a transfer method the liquid such as Novec 1720 of Sumitomo 3M Ltd. The process of processing the surface of the base material body 11 in step S1 in a liquid repellent property with respect to the catalyst functional solution 31 corresponds to the base material surface liquid repellent process.

Next, in step S2 of FIG. 2, as illustrated in FIG. 3B, a trench 21A such as a trench 21 is formed. The trench 21 illustrated in FIG. 3B is a trench that is formed in a position where the connection lines 15 are formed on the circuit interconnection film 17 (circuit interconnection 16). The trench 21 is a groove having a depth-to-width ratio of, for example, equal to or larger than 5.

The trench 21A such as the trench 21 is formed by carving the prepreg 19 by laser processing. As a light source for laser processing, an excimer laser, a CO2 laser, or a YAG (yttrium/aluminum/garnet) laser may be used.

Next, in step S3 of FIG. 2, a desmear process is performed.

As illustrated in FIG. 3C, there is a possibility that smear 22, which is formed by resin that is melted by the laser process, remains on the wall of the trench 21 (21A) or once separated smear 22 drops and remains on the bottom of the trench 21 (21A). Since metal (in this embodiment, copper is used) that forms the circuit interconnection layer 17 is unable to be filled in a portion of the smear 22, it may cause a defect in the circuit interconnection film 17.

The desmear process includes a cleaning process, a smear removing process, a neutralization process, and a cleaning process. The smear removing process, as illustrated in FIG. 3D, is a process of dissolving the smear 22 using a desmear processing solution 30. The desmear processing solution 30 is an etching solution that can dissolve the smear. A cleaning process that is performed before the smear removing process is a process for enabling the desmear processing solution 30 easily injected into the trench 21 by cleaning the trench 21 and the like before performing the smear removing process. The neutralization process is a process of neutralizing the desmear processing solution 30, and the cleaning process that is performed after the neutralization process is a process of cleaning the neutralized desmear processing solution 30.

By performing the desmear process, as illustrated in FIG. 3E, the smear 22 of the trench 21 (21A) is removed.

Next, in step S4 of FIG. 2, the catalyst functional solution 31 is distributed on the trench 21A. The process of distributing the catalyst functional solution 31 on the trench 21A includes a catalyst droplet distribution process and a catalyst liquid invading process.

The catalyst droplet distribution process is performed by landing droplets on a portion having a wide width in the trench 21A using an ink jet type droplet discharge apparatus. The ink jet type droplet discharge apparatus can land droplets on an arbitrary position of a work with a good accuracy by relatively moving a discharge head 41 having a discharge nozzle for discharging the droplets and a work on which the droplets are to be landed and positioning a droplet distribution unit of the work in a position that is opposite to the discharge nozzle with good accuracy. It is possible to make the size of the droplets constant with good accuracy. By using the ink jet type droplet discharge apparatus, a desired amount of catalyst solution can be distributed on a desired portion of the trench 21A. In the process of distributing the catalyst droplets, as illustrated in FIG. 4A, in order to form a land that is connected to an end of the via hole, the catalyst functional solution 31 is distributed by discharging the droplets of the catalyst functional solution 31 toward a land trench 23 and the like formed on an open end portion of a hole 24 below the via hole. The land trench 23 corresponds to a portion having a wide width in the trench 21A.

In the trench 21A, the catalyst functional solution 31 is widely spreaded on a portion having a width that is smaller than the droplet diameter of the catalyst functional solution 31, such as the trench 21, by the catalyst solution filling process. As illustrated in FIG. 4B, for example, the catalyst functional solution 31 distributed on the portion having a wide width such as the land trench 23 is filled into and invades the portion having a narrow width such as the trench 21 by a capillary force. It is preferable that the liquid having a low viscosity is selected as the catalyst functional solution 31 so as to facilitate the suction by the capillary force. A package substrate of most semiconductor devices has an outer dimension of about 3 cm even if it is large. In the trench 21 on the corresponding package substrate, it is confirmed that the invading distance of about 3 cm can be sufficiently realized. The catalyst functional solution 31 is a liquid body including palladium ions, and copper plating is grown, starting from the nucleation site of the metal palladium deposited from the catalyst functional solution 31. Because of this, it is sufficient if the catalyst functional solution 31 is distributed to the extent that it is possible to insert the nucleation sites of the palladium in some places at a density enough to deposit the deposition metal, but it is not necessary for the catalyst functional solution 31 to have the function as a conductive layer. In the respective portions of the trench 21A, it is sufficient if the catalyst functional solution 31 is distributed to the extent that there is no problem in the deposition rate, and it is unnecessary to distribute the catalyst functional solution 31 uniformly.

Next, in step S5 of FIG. 2, the catalyst functional solution 31 is calcinated. The calcinating, for example, is performed for 30 minutes to one hour at a calcinating temperature of about 70° C. to 250° C. to remove the solvent of the functional solution. By sintering the catalyst functional solution 31, the palladium ions included in the catalyst functional solution 31 becomes metal palladium to form a layer of catalyst for forming the conductive layer inside the trench 21A. The catalyst functional solution 31 corresponds to the functional solution that includes the catalyst for forming the conductive layer.

Next, in step S6, by performing a plating process, a circuit interconnection film 17 is formed. The plating process has an electroless plating process and an electro plating process.

In the electroless plating process, as illustrated in FIG. 4C, an electroless plating solution 33 is distributed in an area that includes the trench 21A on which the catalyst film is formed. Metal copper is deposited from copper ions of the electroless plating solution 33 by the catalyst, and as illustrated in FIG. 4D, an interconnection thin film 17a is formed. As the electroless plating solution 33, a redox-Type neutral PH electroless plating solution, which uses metal such as copper as the reducing agent, can be used. Since the corresponding plating solution has a high deposition rate and cause no damage to the base material (base material body 11) or the catalyst layer for forming the conductive layer, it is preferable as the electroless plating solution. Also, it is possible to use a general alkaline plating solution.

In the electro plating process, the circuit interconnection film 17 is formed by laminating metal copper on the interconnection thin film 17a using the interconnection thin film 17a as the conductive layer 17.

Next, in step S7 of FIG. 2, a surface processing layer (liquid repellent layer) formed on the surface of the base material body 11 in step S1 is removed. The removal of the surface processing layer is to prevent the influence of the existence of the surface processing layer when the base material body 11 on which the circuit interconnection 16 is formed is further processed. Of course, if there is no influence during the further processing or if it is not necessary to further process the base material body 11, the surface processing layer may not be removed.

By performing step S7, the circuit interconnection film 17 is formed on the base material body 11 to terminate the circuit interconnection forming process for forming the circuit interconnection 16.

Hereinafter, effects according to the embodiments of the invention will be described. In this embodiment, the following effects can be obtained.

(1) The connection lines 15 correspond to the circuit interconnection film 17 that has a large cross-section having a thickness that is larger than the width thereof. Accordingly, since the reduction of the cross-sectional area of the connection lines 15 according to the reduction of the line width of the connection lines 15 can be suppressed, the deterioration of the conductivity capability of the connection lines 15 caused by reducing the line width of the connection lines 15 is suppressed, and thus the line width and the distribution pitch of the connection lines 15 can be shortened.

(2) The surface of the base material body 11 is processed by a liquid repellent process with respect to the catalyst functional solution 31. Accordingly, the catalyst functional solution 31 can be prevented from attaching to the surface of the base material body 11. If the catalyst function solution 31 is attached to the surface of the base material body 11, a conductive film is also formed on the surface of the base material body 11, and there is a possibility that the adjacent connection lines 15 may be short-circuited by the corresponding conductive film. By performing a liquid repellent process with respect to the surface of the base material body 11, such possibility of the short circuit can be decreased.

(3) The trench 21A is formed by carving the prepreg 19 by a laser process. Using the laser process, the trench 21A can be promptly formed in an accurate shape. The trench having a depth that is larger than the width thereof, such as the trench 21, can be easily formed.

(4) In the process of distributing catalyst droplets, the catalyst functional solution 31 is distributed by discharging the droplets of the catalyst functional solution 31 to the land trench 23 and the like. By determining the portion having a wider width than that of other portions of the trench 21A, such as the land trench 23, as the landing position of the droplets of the catalyst functional solution 31, the droplets of the catalyst functional solution 31 are prevented from landing on a portion that secedes from the trench 21A.

(5) With respect to the portion having a width that is narrower than the diameter of the droplets of the catalyst functional solution 31 such as the trench 21, the catalyst functional solution 31 distributed on a portion having a wide width such as the land trench 23 is filled into and invades a portion having a narrow width such as the trench 21 by a capillary force, and by this catalyst solution flowing process, the catalyst functional solution 31 is widely spreaded. Accordingly, the catalyst functional solution 31 can be distributed in a fine portion such as the trench 21. Also, when the catalyst functional solution 31 is distributed, the catalyst functional solution 31 is prevented from being attached to a portion that secedes from the trench 21A.

(6) The plating process has an electroless plating process and an electro plating process. By performing the electro plating process, the circuit interconnection film 17 can be formed in a short time in comparison to the electroless plating process.

Although preferred embodiments of the invention have been described with reference to the accompanying drawing, the preferred embodiment is not limited thereto. Diverse modifications can be made within the range that does not secede from spirit of the invention, and embodiments can be performed as follows.

### Modified Example 1

In the above-described embodiment, the plating process of the circuit interconnection forming process has the electroless plating process and the electro plating process, but it is not essential to perform the electro plating process together with the electroless plating process. The circuit interconnection forming method may be a method of forming the circuit interconnection film only by the electroless plating process.

### Modified Example 2

In the above-described embodiment, the catalyst functional solution 31 is distributed on the trench 21A using the ink jet type droplet discharge apparatus, but it is not essential to use the ink jet type droplet discharge apparatus to distribute the functional solution that includes the catalyst for forming the conductive layer. Any droplet discharge apparatus that is different from the ink jet type droplet discharge apparatus may be used, and the functional solution may be distributed using another apparatus that is different from the droplet discharge apparatus.

### Modified Example 3

In the above-described embodiment, in the process of forming the circuit interconnection, a desmear process including a cleaning process, a smear removing process, a neutralization process, and a cleaning process is performed. However, performing of the desmear process is not essential. If it is possible to suppress the occurrence of smear when the trench is formed, the process of forming the circuit interconnection may be a process that does not include the desmear process.

### Modified Example 4

In the above-described embodiment, in the process of forming the circuit interconnection, a desmear process including a cleaning process, a smear removing process, a neutralization process, and a cleaning process is performed.

In the smear removing process, as the smear 22 is dissolved by the desmear processing solution 30, the wall surface of the trench 21A is also dissolved. The dissolving of the wall surface of the trench 21A may mean that the shape of the trench 21A is damaged or the wall surface of the trench 21A is finely dissolved to form a fine hole. Under the assumption that the shape of the trench 21A is destroyed, it is preferable that the smear removing process in the desmear process is not performed. Also, it is further preferable that the liquid repellent process performed in step S1 is performed with respect to the desmear processing solution 30 for the desmear process. Under the assumption that the fine hole is formed on the wall surface of the trench 21A, the fine hole on the wall surface accelerates the suction of the catalyst functional solution 31, and improves the adhesion of the copper deposited from the electroless plating solution 33. Accordingly it is preferable to perform the smear removing process. It is preferable to determine whether to perform the smear removing process, or performance conditions in consideration of the above-described conditions.

### Modified Example 5

In the above-described embodiment, the liquid repellent process is performed using a CF4 plasma process. However, it is not essential that the processing method that is used to perform the liquid repellent process with respect to the base material surface is the CF4 plasma process. As described above, the forming of the liquid repellent film may be performed by spreading a modification solution for modifying the material to have a liquid repellent property or by depositing the liquid repellent film through spreading of the liquid body that includes the material of the liquid repellent film. Also, the liquid repellent film may be formed by spreading a liquid repellent functional solution on a sheet such as a film and transferring the liquid repellent functional solution on the sheet to the base material surface through lamination of the corresponding film on the base material. The method of transferring the liquid repellent functional solution to the base material surface may be performed through selection of the position of the base material surface. For example, the liquid repellent process can be performed only with respect to the portion in which a fine trench is formed. After the trench is formed, only the base material surface can be selectively processed without affecting the trench.

The entire disclosure of Japanese Patent Application No. 2010-010722, filed Jan. 21, 2010 is expressly incorporated by reference herein.

What is claimed is:

1. A method of forming a circuit interconnection on a circuit board comprising:
forming a trench that corresponds to a shape of the circuit interconnection on an interconnection base material that forms the circuit interconnection;
distributing a catalyst for forming a conductive layer on the trench; and
forming a conductive circuit interconnection film that forms the circuit interconnection by distributing a plating solution in a range that includes the trench and depositing a conductive material from the plating solution through the catalyst for forming the conductive layer.

2. The method according to claim 1, wherein the distributing of the catalyst comprises distributing a functional solution that includes the catalyst for forming the conductive layer,
wherein performing a liquid repellent process of the base material surface of the interconnection base material with respect to the functional solution that includes the catalyst for forming the conductive layer is provided, and is performed prior to the forming of the trench.

3. The method according to claim 1, wherein the trench is formed by a laser process in the forming of the trench.

4. The method according to claim 1, further comprising processing a desmear.

5. The method according to claim 1, wherein the distributing of the catalyst comprises landing and distributing the functional solution that includes the catalyst for forming the conductive layer on a portion of the trench using an ink jet type discharge device.

6. The method according to claim 1, wherein the distributing of the catalyst comprises distributing the functional solution that includes the catalyst for forming the conductive layer on a portion having a wide width of the trench, and distributing the distributed functional solution on the portion except for the portion having wide width by capillary force.

7. The method according to claim 1, wherein the forming of the film comprises forming the circuit interconnection film by electroless plating.

8. The method according to claim 1, wherein the forming of the film comprises forming the circuit interconnection film by electroless plating and forming the circuit interconnection film by electro plating.

9. A circuit board comprising:
a circuit interconnection that is formed using a method of forming a circuit interconnection which includes forming a trench that corresponds to a shape of the circuit interconnection on an interconnection base material that forms the circuit interconnection; distributing a catalyst for forming a conductive layer on the trench; and forming a conductive circuit interconnection film that forms the circuit interconnection by distributing a plating solution in a range that includes the trench and depositing a conductive material from the plating solution through the catalyst for forming the conductive layer.

10. The circuit board according to claim 9, wherein the distributing of the catalyst comprises distributing the functional solution that includes the catalyst for forming the conductive layer on a portion having a wide width of the trench, and distributing the distributed functional solution on the portion except for the portion having wide width by capillary force.

11. A circuit interconnection film, which has a film thickness that is larger than a width of the interconnection film, and is formed using a method of forming a circuit interconnection film that comprises forming a trench that corresponds to a shape of the circuit interconnection film on an interconnection base material that forms the circuit interconnection film; distributing a catalyst for forming a conductive layer on the trench; and forming a conductive circuit interconnection film by distributing a plating solution in a range that includes the trench and depositing a conductive material from the plating solution through the catalyst for forming the conductive layer.

12. The circuit interconnection film having a film thickness that is larger than a width of the interconnection film according to claim 11, wherein the distributing of the catalyst comprises distributing the functional solution that includes the catalyst for forming the conductive layer on a portion having a wide width of the trench, and distributing the distributed functional solution on the portion except for the portion having wide width by capillary force.
